(19) United States
(12) Patent Application Publication
(10) Pub. No.: US 2015/0316595 A1
(43) Pub. Date: Nov. 5, 2015

(54) LED METER BOARD FOR A TRANSFER SWITCH

(71) Applicant: Milbank Manufacturing Co., Kansas City, MO (US)

(72) Inventors: Paul Creekmore, Kansas City, MO (US); Jason David Bridges, Kansas City, MO (US); Bowe Neuenschwander, Kansas City, MO (US); John Siglock, Kansas City, MO (US); David Lawrence Oldroyd, Kansas City, MO (US)

(73) Assignee: Milbank Manufacturing Co., Kansas City, MO (US)

(21) Appl. No.: 14/702,244

(22) Filed: May 1, 2015

Related U.S. Application Data
(60) Provisional application No. 61/988,013, filed on May 2, 2014.

(51) Int. Cl. G01R 21/133; G01R 21/06

(52) U.S. Cl. CPC G01R 21/1333; G01R 21/06

(57) ABSTRACT

Aspects of the present disclosure involve a light emitting diode (LED) meter board for a transfer switch configured to indicate the power currently being output by the transfer switch to any engaged circuits. In one particular embodiment, the LED meter board indicates a percentage of available power provided to the circuits by a generator or other alternative power source. As more power is output to the circuits, the LED meter board drives the activation of one or more LEDs. Further, the LEDs of the meter board may indicate the power currently being output by the transfer switch to any engaged circuits by blinking at various rates. The blinking rate of the LEDs may increase until one or more of the LEDs may remain solidly lit, or otherwise activated, indicating the percentage of power provided by the generator has reached a particular threshold value.

### CROSS-REFERENCE TO RELATED APPLICATIONS

This application claims priority under 35 U.S.C. §119(e) to U.S. Provisional Application No. 61/988,013 entitled “LED METER BOARD FOR A TRANSFER SWITCH”, filed on May 2, 2014 which is incorporated by reference in its entirety herein.

### FIELD OF THE DISCLOSURE

Aspects of the present disclosure generally relate to systems and methods related to providing and managing utility power sources. More specifically, the present disclosure relates to a manual transfer switch to transfer an electrical load between two or more separate power systems.

### BACKGROUND

Generators are often used in certain situations to feed electrical power to residential and/or commercial load circuits during a utility power outage. Thus, during a power outage, a power transfer switch may switch the residential and/or commercial load circuits from the utility source to the backup generator. As shown in FIG. 1 and as understood to be conventional in power transfer devices, a generator 104 is typically connected to a power inlet box 106 mounted to an exterior wall of a building. The power inlet box 106 is further electrically connected to a transfer switching mechanism 108 that continues the electrical path through circuit breakers associated with the transfer switching mechanism to supply power to certain selected circuits of the load circuit in the main switch panel as determined by the transfer switching mechanism circuit breakers 110. The circuits of the transfer switching mechanism 108 are wired to selected circuits of the load center, through wiring housed within a conduit extending between the load center and the transfer switching mechanism. Thus, through manual operation of the switches in the transfer switching mechanism, a user of the system can select between utility power supplied to the load circuit through a utility meter 102 and generator power supplied by the generator 104 to power the selected circuit of the load center. As an example, during a utility power outage, a user may start up the generator and manually switch the input electrical power from utility power to generator power in order to restore power to pre-designated, critical circuits (e.g., hot-water heater, refrigerator).

Backup generators are limited in how much power they are able to produce. If the user draws too much power from the generator 104 it will stall, resulting in a power failure for all of the circuits it is supplying. As such, information concerning the amount of power provided by the generator 104 to power the selected circuits is useful to ensure that the generator is not overloaded. Inaccurate power meters indicating the power provided by the generator 104 to the circuits may result in one or more of the circuits losing power. It is with these and other issues in mind that the present disclosure was contemplated.

### SUMMARY

One implementation of the present disclosure may take the form of a power meter associated with a power transfer switch. The power meter comprises a display comprising a plurality of light emitting diodes (LED), with each one of the plurality of LEDs corresponding to a particular range of percentage values of a maximum available power from a power source in electrical communication with the power transfer switch and a meter circuit comprising a processor and at least one memory device. The processor executes one or more instructions stored in the at least one memory device, the instructions causing the meter circuit to perform operations. Those operations include calculating a first provided percentage value of a known maximum available power of the power source to a load center, the first provided percentage value of the known maximum power comprising a first current power value provided by the power source to the load center divided by the known maximum available power level of the power source. Further, a first one of the plurality of LEDs blinks at a first blinking rate, the first blinking rate corresponding to the calculated first provided percentage value of the known maximum available power of the power source to the load center.

Another implementation of the present disclosure may take the form of a method for indicating a power level of a power source. The method includes the operations of measuring a first current power value provided by a power source in electrical communication to a load center through a power transfer switch and calculating a first provided percentage value of the known maximum available power of the power source to the load center, the first provided percentage value of the known maximum power comprising the first current power value provided by the power source to the load center divided by the known maximum available power level of the power source. The method further includes the operation of transmitting at least one control signal to a display associated with the power transfer switch, the display comprising a plurality of light emitting diodes (LED), with each one of the plurality of LEDs corresponding to a particular range of percentage values of the known maximum available power from the power source. In one embodiment, the first one of the plurality of LEDs blinks at a first blinking rate, the first blinking rate corresponding to the calculated first provided percentage value of the known maximum available power of the power source to the load center.

Yet another implementation of the present disclosure may take the form of a power transfer switch. The power transfer switch comprises a switch comprising a first position that provides power from a first power source to a load center in electrical communication with the power transfer switch and a second position that provides power from a second power source to the load center, a display comprising a plurality of light emitting diodes (LED) for displaying an indication of a power level provided by the power transfer switch to the load center, and a control circuit comprising a processor and at least one memory device. The processor executes one or more instructions stored in the at least one memory device, causing the control circuit to obtain a maximum available power level of the second power source in the at least one memory device, the maximum available power level of the second power source associated with an overload condition of the second power source and calculate a first provided percentage value of the maximum power of the power source to the load center, the first provided percentage value of the maximum power comprising a first current power value provided by the power source to the load center divided by the maximum available power level of the power source. Further, each one of the plurality of LEDs of the power meter corresponds to a particular range of percentage values of the maximum available power from the power source and a first one of the plurality of LEDs blinks at a first blinking rate, the first blinking rate corresponding to the calculated first provided percentage value of the maximum available power of the power source to the load center.

### BRIEF DESCRIPTION OF THE FIGURES

Aspects of the present disclosure may be better understood and its numerous objects, features, and advantages made apparent to those skilled in the art by referencing the accompanying drawings. It should be understood that these drawings depict only typical embodiments of the present disclosure and, therefore, are not to be considered limiting in scope.

FIG. 1 is an example of a dual-power system that receives power from a utility and a generator.

FIG. 2 is an example transfer switch and associated breakers with an LED meter Board.

FIG. 3A is a front view of a faceplate of a transfer switch incorporating a power meter display with a learn function interface.

FIG. 3B is a side view of a faceplate of a transfer switch incorporating a power meter display with a learn function interface.

FIG. 3C is a back view of a faceplate of a transfer switch incorporating a power meter display with a learn function interface.

FIG. 4 is a front view of an LED meter board for use with a transfer switch.

FIG. 5 is a block diagram of the LED meter board.

FIG. 6 is a schematic of a self-powering and current sensing circuit for the LED meter board.

FIG. 7 is a graph illustrating the blinking rates of each LED as a function of power output.

### DETAILED DESCRIPTION

Aspects of the present disclosure involve a light emitting diode (LED) meter board for a transfer switch. The LED meter board is configured to indicate the power currently being output by the transfer switch to any engaged circuits. In one particular embodiment, the LED meter board indicates a percentage of available power provided to the circuits by a generator or other alternative power source. As more power is output to the circuits, the LED meter control circuit drives the activation of one or more LEDs. Additional LEDs are activated as a higher percentage of the available power is provided to the load, until every LED is solidly or continuously lit or an overpower situation occurs. In the past, analog power meters may have been associated with a transfer switching mechanism to measure the power being provided by the backup generator and thereby help the user prevent a power overload of the generator. One issue with these analog power meters, however, is that they do not indicate the percentage of load that the generator is operating at, causing the user to have to guess whether more or fewer circuits can be attached. Another issue is that during a power failure, there may not be any ambient light available to read the analog meter. Thus, the LED meter board described herein provides a more accurate measurement of the power provided to the circuits (based on a percentage of maximum power available from the generator) that may be read in most lighting environments.

In one particular embodiment, the LEDs of the meter board may indicate the power currently being output by the transfer switch to any engaged circuits by blinking at various rates. For example, one or more of the LEDs may blink at a first rate when a low percentage of the available power is being provided by the generator. At a higher percentage of provided power, one or more of the LEDs may blink at a faster rate, indicating the higher percentage of available generator power being provided. The blinking rate of the LEDs may increase until one or more of the LEDs may remain solidly or continuously lit, or otherwise activated, indicating the percentage of power provided by the generator has reached a particular threshold value. One or more of the blinking LEDs of the meter board may be provided for a range of percentage of power provided, such that the threshold value for any one LED corresponds to an upper limit for that particular range associated with the LED. In this manner, a higher resolution display indicating the percentage of provided power is available for users of the transfer switch mechanism.

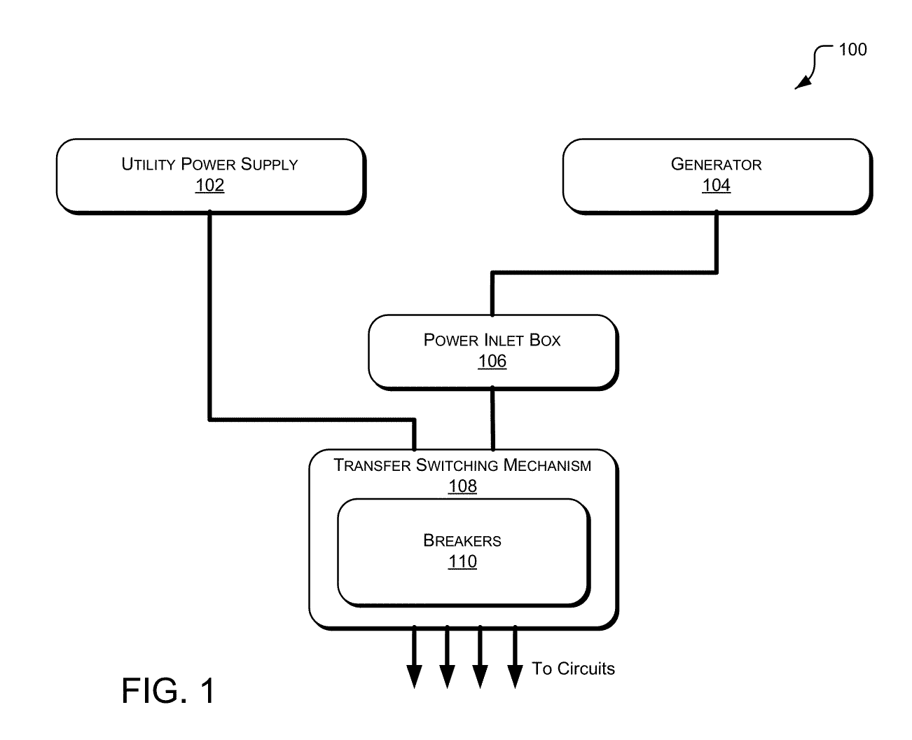

As discussed above, FIG. 1 illustrates a generator 104 connected to a power inlet box 106 mounted to an exterior wall of a building. The power inlet box 106 is further electrically connected to a transfer switching mechanism 108 that continues the electrical path through circuit breakers associated with the transfer switching mechanism to supply power to certain selected circuits of the load circuit. The transfer switching mechanism may be a manual transfer switch or an automatic transfer switch. As such, any mention of a transfer switch in this disclosure contemplates any type of power transfer switch. The circuits of the transfer switching mechanism 108 are wired to selected circuits of the load center, through wiring housed within a conduit extending between the load center and the transfer switching mechanism. Thus, through manual operation of the switches in the transfer switching mechanism, a user of the system selects between utility power supplied to the load circuit through a utility meter 102 and generator power supplied by the generator 104 to power the selected circuit of the load center.

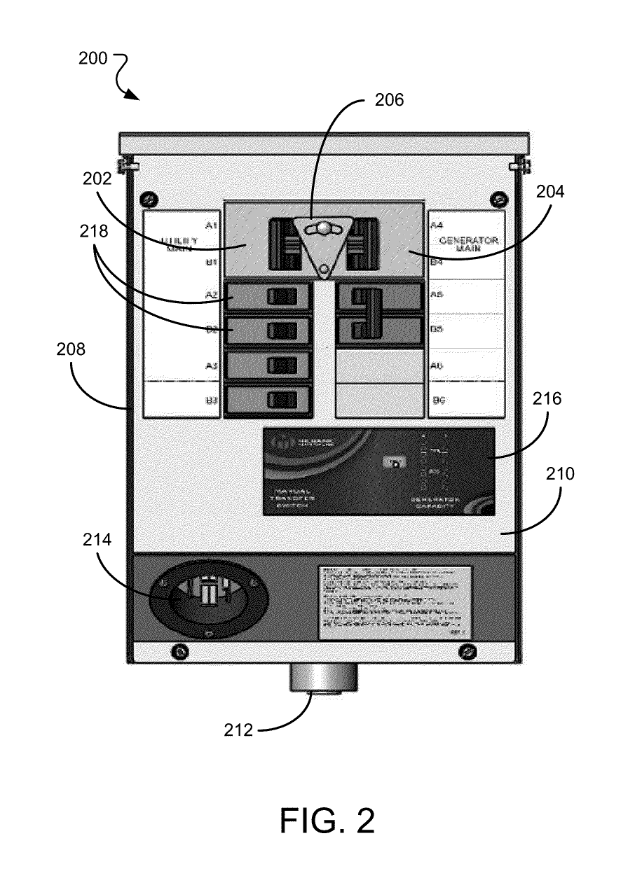

FIG. 2 is a front view of an example transfer switch 200, such as the transfer switch mechanism 108 of FIG. 1. In general, the transfer switch 200 connects two or more power sources to a load center, such as a home or commercial building. In one particular example used herein, the transfer switch 200 allows a user to switch between a utility power source and an alternative power source, such as a generator, for providing power to the load center. It is often the case that the transfer switch would be used when there is a power failure at the load center location. In the case of a home, the load center might include a refrigerator circuit, some light circuits, a hot-water heater circuit, and other circuits that have need for power during a failure. In general, however, any type and number of circuits may be powered by the generator as determined by a user of the transfer switch, as long as the circuits do not draw too much of the available generator power to cause the generator to stall.

The transfer switch 200 includes interfaces for connecting the power sources to the transfer switch. For example, the transfer switch 200 includes a first connector 202, such as a breaker switch, to which a utility power source may be electrically connected. In addition, the transfer switch 200 may include a second connector 204 to which an alternative power source, such as a generator, may be electrically connected. In one embodiment, an interlock device 206 is utilized between the first connector 202 and the second connector 204 to ensure that only one power source is powering the load center at any one time. This interlock 206 prevents unsafe conditions that may cause fire, electrocution, damage to the load center or many other unsafe conditions.

During an outage of utility power (or for any other reason), a user of the transfer switch 200 may operate the breaker switch of the first connector 202 to remove an electrical connection between the utility power source and the load center (or powered circuits). In addition, the user may activate the breaker switch of the second connector 204 to provide an electrical connection between the generator power source and the load center. In one embodiment, the disconnection of the utility power source to the load center and the connection of the generator power source to the load center may occur simultaneously. Once the second connection 204 is activated, the circuits of the load center are powered by the generator power source. In some embodiments, the generator power source may be any type of power source, including wind power, solar power, or an additional utility power source.

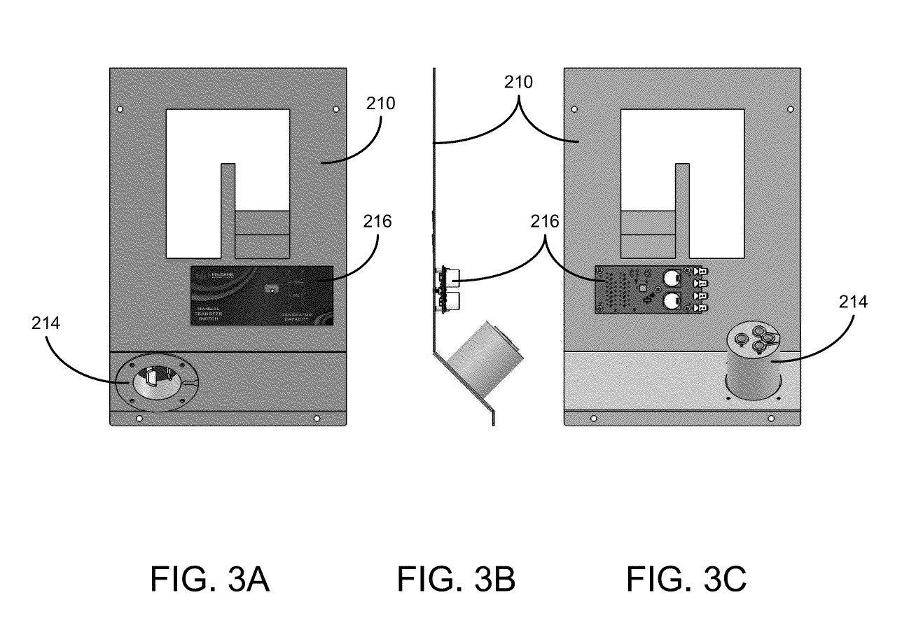

In general, the transfer switch includes a rectangular housing 208 and a faceplate 210 mounted within the housing. The faceplate 210 may include one or more cutouts for one or more breakers 218, a plug interface 214 for receiving power from a generator and an LED meter board 216. The aspects of the faceplate 210 and the various components associated with the faceplate are discussed in more detail below with reference to FIGS. 3A-6.

To connect the transfer switch 200 such that the switch can provide power to the load center, utility wires from the load center connect to a set of breakers 218 from an opening 212 in the bottom of the housing 208. Output wires to the load center are also passed through the opening 212 in the bottom of the housing 208. Activation of a combination of the power switches 202, 204 and the breakers 218 connected to the load center allow a user of the transfer switch 200 to provide power to various circuits of the load center from utility power source or the alternative power source. However, as mentioned, the power available from the alternative power source, such as a generator, may be limited such that drawing too much power from the alternative power source may cause the generator to overload or stall. Therefore, the transfer switch 200, in particular the faceplate 210 of the transfer switch, may include a power meter board 216 that provides an indication of the percentage of maximum power available from the generator being provided to the circuits of the load center. Various aspects of features of the meter board 216 are described below.

FIG. 3A is a front view, FIG. 3B is a side view, and FIG. 3C is a back view of the faceplate 210 of a transfer switch 200 incorporating the meter board 216. In general, the meter board 216 includes a display comprising a plurality of LED indicator lights disposed on the meter board that provide a visual indication of the power being provided to the load center from either the utility power source or the alternative power source. In the embodiment illustrated in FIGS. 2 and 3A-3C, the LED meter board 216 includes a series of light emitting diodes (LEDs) that indicate an approximate power provided to the load center. In particular, the LEDs are activated and deactivated to indicate the power being provided.

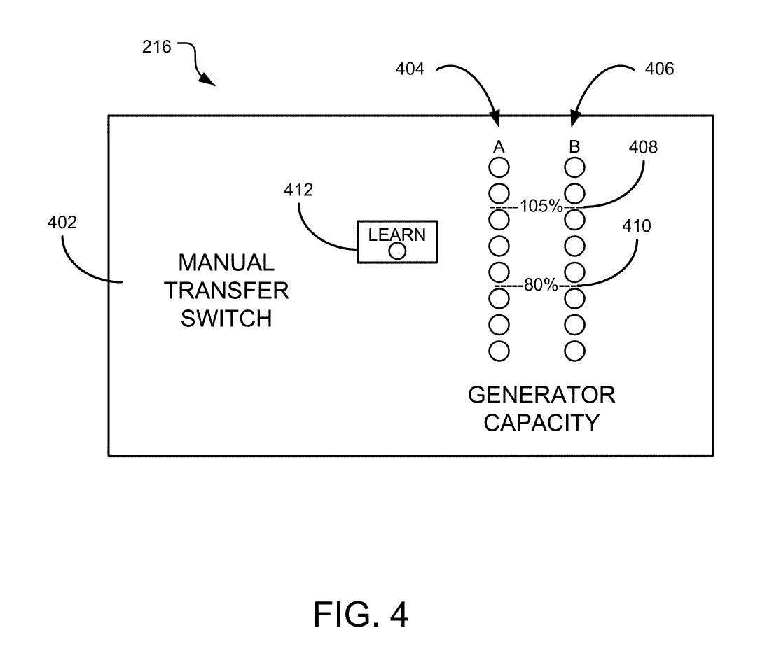

FIG. 4 is a front view of an LED meter board for use with a transfer switch. The LED meter board 216 of FIG. 4, in general, provides an indication of the power provided to the load center as a percentage of the maximum power available from the alternative power source, such as a generator. Thus, the front view or face 402 of the meter board 216 includes at least one series of LED indicator lights 404 such that each of the LED indicator lights in the series of such lights corresponds to a percentage of available generator power being provided to the load center through the transfer switch mechanism. The series of LED indicator lights 404 may include any number of LED devices that may be lit by a control circuit in electrical communication with the series of LED lights 404. The operation of the control circuit to operate the LED indicator lights 404 in response to the amount of power provided to the circuits in electrical communication with the generator (or other alternative power source) is described in more detail below.

The spectrum displayed by the LED meter board 216 by the one or more series of LED lights 404 ranges from 0% to 100% of the available power from the generator. For example, in an embodiment that utilizes four LED lights in the series of LED lights 404, the LEDs of the display may be arranged in a vertical or horizontal fashion where the bottom-most (or left-most) LED indicates the 0%-25% range of the power of the generator being provided to the load center, the next LED in the series moving up (or to the right) along the series of lights indicates that 25%-50% of the maximum power output of the generator is being provided to the load center, the next LED in the series indicates that 50%-75% of the maximum power output of the generator is being provided to the load center, and the upper-most (or right-most) LED indicates that 75%-100% of the maximum power output of the generator is being provided to the load center. Thus, when the LED corresponding to a particular range is illuminated, the upper percentage for the range associated with the LED light is being provided. For example, if the lowest LED light is illuminated in the series 404, the generator is providing at least 25% of available power. The percentage of available power may continue to increase until the amount of power provided reaches or exceeds 50% of the available power. When the power provided reaches or exceeds 50% of the available power, the second LED light in the series 404 may be illuminated by the controller circuit. In this manner, the various LEDs of the series 404 provide an indication of the percentage of the generator power being consumed by the load center. A user of the transfer switch mechanism may then determine an estimated percentage of generator power being provided and may adjust the number of load circuits or amount of power one or more of the load circuits consumes in response to the power consumption indication.

Although discussed above as having four LED lights in the series 404, in general, the series of LED lights may include any number of such lights and the percentages of the generator power indicated on the LED meter board 216 may include any percentage range, including those exceeding 100% of the generator power. For example, the particular series of LED lights 404 illustrated in the meter board 216 of FIG. 4 includes eight (8) LED light indicators oriented vertically on the meter board face 402. Similar to above, the LED lights may be activated from the bottom to the top of the series 404 to indicate a percentage of overall generator power being sent to the load center. Thus, the meter board face 402 may also include one or more percentage markers 408, 410 located adjacent or near the series 404 of LED lights. The percentage markers 408, 410 provide an indication of the percentage of generator power provided through the transfer switch for one or more of the LED lights. In the embodiment shown in FIG. 4, a first percentage marker 410 labels an LED that indicates that the load center is providing 80% of the generator's maximum power and a second percentage marker 408 labels an LED that indicates that the load center is providing 105% of the generator's maximum power. However, the meter board 216 may include any number of percentage markers 408, 410 for any number of LEDs in the series 404.

In addition, the power meter board 216 may be configured to provide a power measurement in percentage of generator power for each phase of a multi-phase system. In particular, the generator may provide power to the load center in two phases, similar to a utility power source. Thus, the meter board 216 may include two series of LED indicator lights 404, 406, one for each phase of the two-phase power provided. As shown in FIG. 4, the meter board 216 includes a first series 404 of LED lights for a first phase of the power provided and a second series 406 of LED lights for a second phase of the power provided. Each series 404, 406 of lights indicates the percentage of the generator's maximum power provided by the selected source for each phase. The power meter board 216 may include any number of series of LED lights for any aspect of the power provided by the generator, including but not limited to the phases of the generator power.

Additionally, the power meter board 216 may include a learn function 412 to determine the capacity of the connected generator to the transfer switching mechanism. In general, by activating the learn function 412, such as through pressing a button located on the power meter board face 402, the transfer switching device 216 may determine the capacity of the power provided by the generator. In particular, a component or circuit associated with the power meter board 216 may determine a maximum power provided by the generator or other alternative power source, and adjust the power meter display 404, 406 so that the display may be used for any size generator and display the full range of the generator. As such, the power meter display of the present disclosure eliminates the need for the user to understand the power rating of their generator and simply illustrates the proper operating range for the connected generator. In one particular embodiment, the learning function is accomplished by activating the learn mode of the power meter 216 (such as by pressing the learn function button 412 on the face 402 of the meter board) and then turning on devices and loads of the load center until the generator stalls. The microcontroller records the max generator power that was measured before the generator stalled and saves it to non-volatile memory as the 100% setting for that particular generator. Further, any time the generator is serviced or replaced, the user can re-run the learn mode to readjust the power meter display to correspond to the attached generator. The determination of the capacity of a connected generator using a learn function of the LED meter board is described in more detail in related concurrently-filed patent application titled “TRANSFER SWITCH WITH MAXIMUM POWER LEARN FUNCTION” to Creekmore et al., Attorney Docket No. MIL228-491919, which is incorporated in its entirety herein.

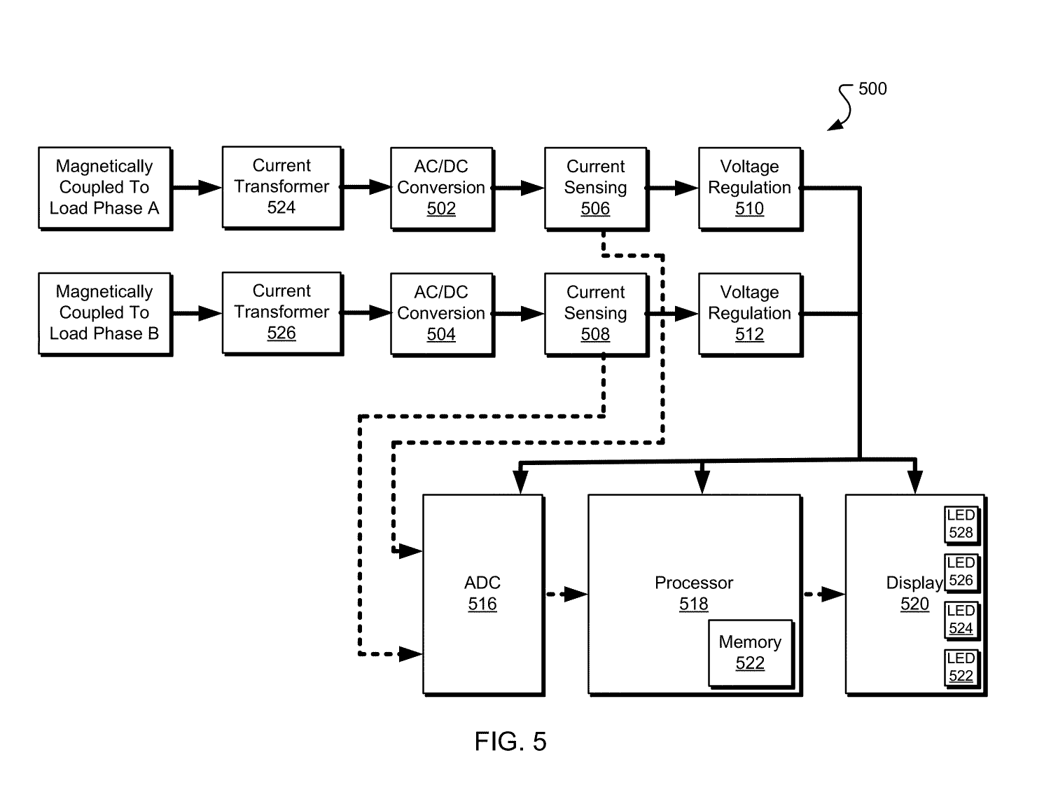

Referring now to FIG. 5, a block diagram representing one implementation of an LED meter board 500 is shown. The meter circuit 500 includes two parallel measurement and power systems accordingly, one for each phase measured (labeled in FIG. 5 as “Load Phase A” and “Load Phase B”). In general, each channel of the meter circuit 500 measures the power provided by a single phase from a power source (such as a generator as discussed above) and provides a displayed measurement. In one embodiment, the circuit 500 is included with a transfer switch mechanism as discussed above to provide an indication of the percentage of the maximum power available from the alternative power source that is being provided. However, the circuit 500 may be utilized with any system to indicate a percentage of power provided by a power source to a load or load center.

Each measurement channel includes a current transformer (CT) 524, 526 magnetically coupled to one or more phases of the power system, an alternating current to direct current (AC to DC) converter 502, 504, a current sensing circuit 506, 508, and a voltage regulation circuit 510, 512. In general, the CTs 524, 526 output an AC signal with current proportional to the current flowing through the coupled load conductors. The AC to DC converters 502, 504 for each measurement channel convert the AC output from the CTs 502, 504 to a DC signal. The DC signals from the AC to DC converters 502, 504 are transmitted to the current sensing circuits 506, 508 that generate a signal with voltage proportional to the current flowing through the sensing circuit. The output signals from the current sensing circuits 506, 508 are transmitted to an analog to digital converter (ADC) 516. The ADC 516, in turn, outputs a digital representation of the measured output current provided by the current sensing circuits 506, 508 to a processor 518 or processing circuit. In another embodiment, the ADC 516 functionality is performed by the processor 518 through the execution of one or more instructions such that the output signals from the current sensing circuits 506, 508 are transmitted to the processing device.

The processor 518 includes any general purpose processor, microcontroller, computer or the like and includes one or more memory devices 522 for storing instructions. The memory devices 522 may include a dynamic storage device or random access memory (RAM) or other computer-readable devices coupled to the processor 518 for storing information and instructions to be executed by the processor. Execution of the instructions or program contained in memory devices 522 may cause the processor 518 to perform one or more process steps. Further, the power levels provided by the generator during the learn function described above may be stored in the one or more memory devices 522 associated with the processor 518. In alternative embodiments, circuitry may be used in place of or in combination with the software instructions. Thus, embodiments of the present disclosure may include both hardware and software components.

In particular, the processor 518 may execute a program that is stored in the memory, where the program instructs the processor to compare the received current measurements from the ADC 516 to a maximum output current value stored in the memory of the processor. Through this comparison, a percentage of the received current value of the maximum output current value is calculated. In general, the calculated percentage is a percentage of provided power (for each phase of the provided power, in one embodiment) from an alternative power source, such as a generator. For example, the received current value may be 50% of the stored maximum output current, indicating that the transfer switch device is receiving 50% of the power available from the generator, in that particular phase. Once calculated, the processor generates one or more instructions for activating one or more LEDs 522-528 of a display 520. In one embodiment, the instructions from the processor 418 to the display 420 include energizing the one or more LEDs 522-528 to activate the LED lights. The instructions from the processor 418 thus activate the one or more LEDs to provide an indication of the calculated percentage of power being provided by the alternative power source, either in total or for the phases of the provided power.

In one example, the meter circuit 500 is configured to draw power from the utility or generator power source through a magnetically coupled current transformer to power the various components of the meter circuit 500. For example, voltage regulators 510, 512 may be included in the circuit 500 configured to receive DC power from the AC to DC converters 502, 504. The output of the voltage regulators 510, 512 may be utilized to power one or more of the components of the meter circuit 500. For example, the voltage regulator 510, 512 outputs may power the components of the ADC 516, the processor 518 and the display 520. In this manner, one or more of the components of the meter circuit 500 may utilize the current delivered by the current transformers to power the components of the circuit. Thus, the use of an off-line power supply, battery, or other connection to obtain power for the circuit is not needed, easing installation of the power meter 500, easing compliance with safety standards, and reducing the cost of the device.

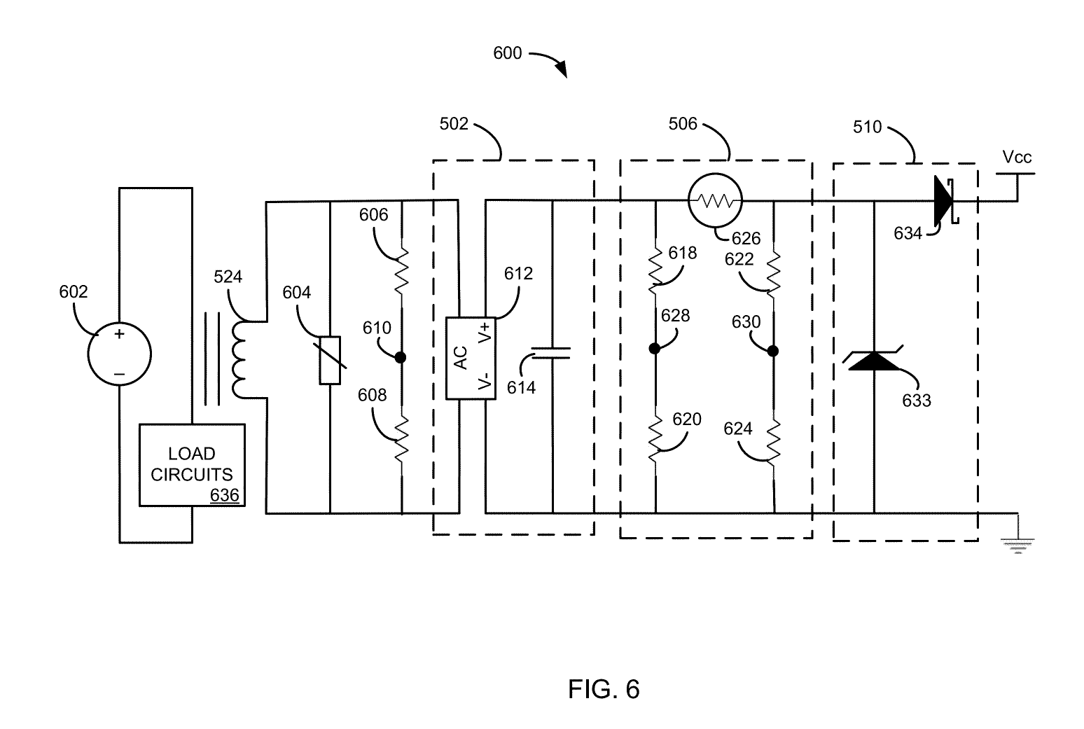

FIG. 6 is a schematic of one embodiment of a meter circuit for a power transfer switch with a learn function. In particular, the circuit 600 is one embodiment of a portion of the circuit diagram 500 discussed above with relation to FIG. 5. In general, the circuit 600 of FIG. 6 provides the current transformer 524, AC to DC converter 502, the current sensing circuit 506, and the voltage regulation 510 for one measurement channel, typically monitoring one phase of power provided to the manual transfer switch. It should be appreciated, however, that the circuit 600 of FIG. 6 is but one type of circuit of the meter circuit and that many other circuit components and constructions may be used to perform the functions of the meter circuit.

As mentioned, the circuit 600 receives the output of a current transformer 524 magnetically coupled to one phase of a multi-phase power source, such as a generator or utility power source, that provides power to one or more load circuits 636. Connected across the output of the current transformer 602 is a varistor component 604 to provide overvoltage protection to the circuit 600. Further connected in parallel to the varistor 604 are a first set of two in-series resistors 606, 608. A connection node 610 is located between the first set of resistors 606, 608 to provide a connection point within the circuit for detecting a drop or change in the frequency of the provided power from the power source 602. This detection node 610 may be used to determine an overload condition of the power source 602 for use with the learn function of the system discussed above. For example, the signal at the detection node 610 may be provided to the ADC 516 as an input, which in turn provides a digital representation of the input to the processor 518. The processor 518 may monitor the input as described above to detect when the frequency of the power signal at the detection node 610 changes.

Further connected in parallel with the two resistors 606, 608 is the AC to DC conversion portion 502 of the circuit 600 including a full-wave rectifier diode bridge 612 and a capacitor 614 connected in parallel with the full-wave rectifier. The current sensing circuit 504 is connected to the AC to DC conversion circuit 502. The current sensing circuit 504 includes a second set of resistors 618, 620 connected in series to each other, a third set of resistors 622, 624 connected in series to each other, and a current sensing resistor 626 connected between one of the resistors 618 of the second set of resistors and one of the resistors 622 of the third set of resistors. A high side connection node 628 is located between the resistors 618, 620 of the second set of resistors and a low side connection node 630 is located between the resistors 622,624 of the third set of resistors. In one embodiment, the ADC 516 may be connected to the high side connection node 628 and the low side connection node 630 so that the processor 518 may compare the voltage at each node and determine the current through the known current sensing resistor 626. This determination by the processor 518 of the current through the current sensing resistor 626 based on the voltage at the high side connection node 628 and the low side connection node 630 may be used by the processor to determine the power provided by the power source 602 to the load center associated with the manual transfer switch where the processor 518 approximates the power source as a known, fixed-voltage source.

In addition, a voltage regulator circuit 510 may be connected to the current sensing circuit 506. The voltage regulator circuit 510 may include a Zener diode 633 connected in parallel with the current sensing circuit 506 and a Schottky diode 634 connected in series with the regulator output, its anode connected to the Zener diode's cathode. These components may operate to provide power to other components of the LED meter circuit as discussed above, such as the processor 518 and the display 520, and the blocking diode 634 permits multiple measurement channel circuits to contribute current to the other components of the LED meter circuit without interfering with each other's measurements. In this manner, power is provided to operate the components of the meter circuit from the CT signal and not, necessarily, directly from the power source 602 or from a battery that would need to be replaced periodically.

In other embodiments of the LED meter circuit, the processor 518 may include one or more of the components of the circuit 600 discussed in FIG. 6. More particularly, the processor 518 may execute instructions that cause the processor to perform the function of one or more of the components of the circuit 600. Further, additional components may also be utilized with the circuit 600 to provide additional functionality to the circuit overall without taking away from the general operation of the LED meter circuit described herein.

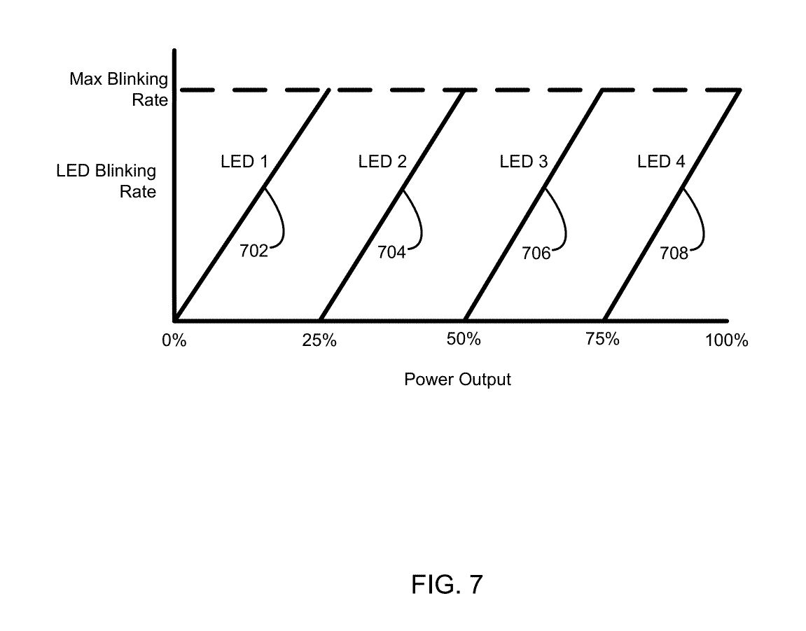

FIG. 7 is a graph depicting an example LED output as a function of percentage of maximum power output. In this example, the display includes four LEDs, although any number of LEDs is contemplated. In the example shown, when power output is at 0%, each of the LEDs is turned off. As power output rises between 0% and 25% the current sensing circuits 506, 508 measure the increased current and provide the measurement to the processor 518 via the ADC 516. The processor 518 compares the measured current to the maximum output current of the generator and determines the number of LEDs to activate. In addition, this example increases the resolution of the display 520 by blinking the top-most activated LED at a variable rate in order to display fractional levels of power within the range represented by that LED. In general, the rate of blinking is proportional to the fractional measurement. In this example, the power output is rising between 0% and 25%. Thus, only the first LED 522 in the series of LEDs, in this example located at the bottom of the vertically oriented LEDs, is activated and as the output power increases, the rate at which the first LED 522 is blinking increases. Although the depicted example shows a linear relationship 702 between the percentage of maximum power and the rate at which the LEDs blink, it should be understood that the relationship need not be linear. For example, the relationship between the blinking and the percentage of power output may be a step function where blinking speed does not increase until one or more thresholds are crossed.

Once the 25% threshold has been surpassed, the first LED 522 may turn on solid, and the second LED 524, located directly above the first LED 522, begins blinking according to the 25%-50% range (shown in FIG. 7 as line 704). Similarly, once the 50% threshold is surpassed, the first and second LEDs 522, 524 remain solid or continuously lit, and the third LED 526 is activated and blinks according to the 50%-75% range (shown in FIG. 7 as line 706). Finally, once the 75% threshold is passed, the first three LEDs 522-526 remain solid and the fourth and top LED 528 is activated (shown in FIG. 7 as line 708). Once the 100% threshold is met, all of the LEDs 522-528 are on solid. This pattern may continue for additional LEDs that indicate the provided power is above the 100% threshold. Thus, a person may quickly observe the current power output as a percentage of the generator's maximum output quickly and easily at any time, including those levels of provided power within the ranges associated with each LED.

The foregoing merely illustrates the principles of the LED meter circuit and associated components. Various modifications and alterations to the described embodiments will be apparent to those skilled in the art in view of the teachings herein. It will thus be appreciated that those skilled in the art will be able to devise numerous systems, arrangements and methods which, although not explicitly shown or described herein, embody the principles of the system and are thus within the spirit and scope of the present disclosure. From the above description and drawings, it will be understood by those of ordinary skill in the art that the particular embodiments shown and described are for purposes of illustrations only and are not intended to limit the scope of the present method. References to details of particular embodiments are not intended to limit the scope of the method.

What is claimed is:

1. A power meter associated with a power transfer switch comprising:
a display comprising a plurality of light emitting diodes (LED), with each one of the plurality of LEDs corresponding to a particular range of percentage values of a maximum available power from a power source in electrical communication with the power transfer switch; and
a meter circuit comprising a processor and at least one memory device, the processor executing one or more instructions stored in the at least one memory device, the instructions causing the meter circuit to:
calculate a first provided percentage value of a known maximum available power of the power source to a load center, the first provided percentage value of the known maximum power comprising a first current power value provided by the power source to the load center divided by the known maximum available power level of the power source;
wherein a first one of the plurality of LEDs blinks at a first blinking rate, the first blinking rate corresponding to the calculated first provided percentage value of the known maximum available power of the power source to the load center.

2. The power meter of claim 1 wherein the calculated first provided percentage value of the known maximum available power of the power source to the load center is within the particular range of percentage values for the first one of the plurality of LEDs.

3. The power meter of claim 1 wherein the first one of the plurality of LEDs blinks at a second blinking rate corresponding to a second provided percentage value of the known maximum available power of the power source to a load center, wherein the second provided percentage value of the known maximum available power is more than the first provided percentage value of the known maximum available power.

4. The power meter of claim 3 wherein the second blinking rate is faster than the first blinking rate.

5. The power meter of claim 1 wherein a second one of the plurality of LEDs is continuously illuminated when the first provided percentage value of the known maximum available power of the power source to the load center exceeds the particular range of the percentage values for the second one of the plurality of LEDs.

6. The power meter of claim 5 wherein the particular range of percentage values of the known maximum available power from the power source corresponding to the second one of the plurality of LEDs is lower than the particular range of percentage values of the known maximum available power from the power source corresponding to the first one of the plurality of LEDs.

7. The power meter of claim 1 wherein the first one of the plurality of LEDs is continuously illuminated when the first provided percentage value of the known maximum available power of the power source to the load center exceeds the particular range of percentage values for the first one of the plurality of LEDs.

8. The power meter of claim 1 wherein the power source is a generator.

9. The power meter of claim 1 wherein executing the one or more instructions stored in the at least one memory device by the processor further causes the meter circuit to:
transmit at least one control signal to the display to cause the first one of the plurality of LEDs to blink at the first blinking rate.

10. The power meter of claim 1 wherein executing the one or more instructions stored in the at least one memory device by the processor further causes the meter circuit to:
monitor a power signal provided from the power source;
detect an overload condition of the power source; and
store the known maximum power level of the power source in at least one memory device, the known maximum power level of the power source associated with the overload condition of the power source.

11. A method for indicating a power level of a power source, the method comprising:
measuring a first current power value provided by a power source in electrical communication to a load center through a power transfer switch;
calculating a first provided percentage value of the known maximum available power of the power source to the load center, the first provided percentage value of the known maximum power comprising the first current power value provided by the power source to the load center divided by the known maximum available power level of the power source; and
transmitting at least one control signal to a display associated with the power transfer switch, the power meter comprising a plurality of light emitting diodes (LED), with each one of the plurality of LEDs corresponding to a particular range of percentage values of the known maximum available power from the power source;
wherein a first one of the plurality of LEDs blinks at a first blinking rate, the first blinking rate corresponding to the calculated first provided percentage value of the known maximum available power of the power source to the load center.

12. The method of claim 11 wherein the calculated first provided percentage value of the known maximum available power of the power source to the load center is within the particular range of percentage values for the first one of the plurality of LEDs.

13. The method of claim 11 wherein the first one of the plurality of LEDs blinks at a second blinking rate corresponding to a second provided percentage value of the known maximum available power of the power source to a load center, wherein the second provided percentage value of the known maximum available power is more than the first provided percentage value of the known maximum available power.

14. The method of claim 13 wherein the second blinking rate is faster than the first blinking rate.

15. The method of claim 11 wherein a second one of the plurality of LEDs is continuously illuminated wherein the first provided percentage value of the known maximum available power of the power source to the load center exceeds the particular range of percentage values for the second one of the plurality of LEDs

16. The method of claim 15 wherein the particular range of percentage values of the known maximum available power from the power source corresponding to the second one of the plurality of LEDs is lower than the particular range of percentage values of the known maximum available power from the power source corresponding to the first one of the plurality of LEDs.

17. The method of claim 11 wherein the first one of the plurality of LEDs is continuously illuminated when the first provided percentage value of the known maximum available power of the power source to the load center exceeds the particular range of percentage values for the first one of the plurality of LEDs.

18. A power transfer switch comprising:
a switch comprising a first position that provides power from a first power source to a load center in electrical communication with the power transfer switch and a second position that provides power from a second power source to the load center;
a display comprising a plurality of light emitting diodes (LED) for displaying an indication of a power level provided by the power transfer switch to the load center; and
a control circuit comprising a processor and at least one memory device, the processor executing one or more instructions stored in the at least one memory device, the instructions causing the control circuit to:
obtain a maximum available power level of the second power source in the at least one memory device, the maximum available power level of the second power source associated with an overload condition of the second power source;
calculate a first provided percentage value of the maximum power of the power source to the load center, the first provided percentage value of the maximum power comprising a first current power value provided by the power source to the load center divided by the maximum available power level of the power source;
wherein each one of the plurality of LEDs of the power meter corresponds to a particular range of percentage values of the maximum available power from the power source and a first one of the plurality of LEDs blinks at a first blinking rate, the first blinking rate corresponding to the calculated first provided percentage value of the maximum available power of the power source to the load center.

19. The power transfer switch of claim 18 wherein the first power source is a utility power source and the second power source is a generator.

20. The power transfer switch of claim 18 wherein the calculated first provided percentage value of the maximum available power of the power source to the load center is within the particular range of percentage values for the first one of the plurality of LEDs.

21. The power transfer switch of claim 18 wherein the first one of the plurality of LEDs blinks at a second blinking rate corresponding to a second provided percentage value of the maximum available power of the power source to a load center, wherein the second provided percentage value of the maximum available power is more than the first provided percentage value of the maximum available power.

22. The power transfer switch of claim 21 wherein the second blinking rate is faster than the first blinking rate.
